(19) United States
(12) Patent Application Publication
(10) Pub. No.: US 2025/0056820 A1
(43) Pub. Date: Feb. 13, 2025

(54) METAL-INSULATOR-METAL DEVICE WITH HIGH-K LAYER CAPPING STRUCTURE

(71) Applicant: Taiwan Semiconductor Manufacturing Company LTD, Hsinchu (TW)

(72) Inventors: Liang-Shiuan Peng, Taipei (TW); Chih-Hung Lu, Zhudong (TW)

(21) Appl. No.: 18/232,942

(22) Filed: Aug. 11, 2023

(51) Int. Cl. H10N 70/00; H01L 21/02

(52) U.S. Cl. CPC H01L 28/40; H01L 21/02181; H01L 21/02189; H01L 21/02194

(57) ABSTRACT

A metal-insulator-metal (MIM) device includes a first metal, a first cap layer disposed on the first metal, an insulator layer disposed on the first cap layer, a second cap layer disposed on the insulator layer, and a second metal disposed on the second cap layer. The first and second cap layers each comprise a dielectric material having a tetragonal crystal phase. In some embodiments, the tetragonal phase percentage of the cap layers is at least 80%. In some embodiments, the insulator layer is a ferroelectric material, such as Hf₁₋ₓZrₓO₂ with an orthorhombic phase percentage of at least 70%. In some such embodiments, the cap layers are ZrO₂ or Hf₁₋ₓZrₓO₂ with a higher Zr fraction than the insulator layer. In some embodiments, the cap layers are doped with a dopant that causes the tetragonal phase percentage of the cap layers to be at least 80%.

### BACKGROUND

The following relates to metal-insulator-metal (MIM) devices, the integrated circuit (IC) arts, ferroelectric device arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, and 3 diagrammatically illustrate side sectional views of metal-insulator-metal (MIM) devices including a high-k insulator with a capping structure according to various embodiments.

FIG. 4 diagrammatically shows a relationship between composition and crystal structure of Hf₁₋ₓZrₓO₂.

FIG. 5 diagrammatically illustrates a side sectional views of an MIM

device including a high-k insulator with a capping structure according to a further embodiment.

FIG. 6 presents some experimental results demonstrating reduced MIM device leakage with increasing ZrO₂ cap thickness.

FIGS. 7 diagrammatically illustrates a side sectional views of an MIM device including a high-k insulator with a capping structure according to a further embodiment.

FIG. 8 diagrammatically illustrates a flow chart of a suitable fabrication flow for fabricating an MIM device including a high-k insulator with a capping structure.

FIG. 9 diagrammatically illustrates a side sectional view of an MIM device including a high-k insulator with a capping structure according to a further embodiment.

FIGS. 10 and 11 diagrammatically illustrate two example applications of MIM devices disclosed herein for reducing noise fluctuations in signals communicated between an integrated circuit (IC) chip and bonding bumps of a redistribution layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” can be used to include any numerical value that can vary without changing the basic function of that value. When used with a range, “about” also discloses the range defined by the absolute values of the one or two endpoints, e.g., “about 0.2 nanometers to about 5nanometers” also discloses the range “0.2 nanometers to 5 nanometers”, and similarly the range “at least about 25% lower” also disclosed the range “at least 25% lower”. The term “about” may refer to plus or minus 10% of the indicated number.

Metal-insulator-metal (MIM) devices are used in various integrated circuit (IC) designs. The basic MIM structure includes an insulator layer sandwiched between first and second metal layers, and can for example serve as a capacitor for frequency filtering, noise reduction, DC isolation, or so forth. To provide the MIM structure with a high capacitance, it can be beneficial for the insulator layer to have a high dielectric constant. In a common notation, a high-k (or high-κ, or high relative permittivity ϵᵣ) dielectric material is a dielectric material that has a dielectric constant κ(=Eᵣ) that is larger than the dielectric constant of silicon dioxide (SiO₂, κ=3.9). The capacitance C of an MIM

$$C = \frac{{κε}_{0} A}{d}$$

structure is given by where K and t are the dielectric constant and thickness, respectively, of the insulator layer, and ϵ₀ is the permittivity of free space (i.e. vacuum). It can be seen that the capacitance C can thus be increased (for a given area A of the MIM) by reducing the thickness d of the insulator layer, and/or by increasing its dielectric constant κ, thus motivating toward MIM structures having a high-k insulator layer with reduced thickness d.

In some applications, the insulator layer of the MIM structure may be desired to be a ferroelectric material. For example, an MIM with a ferroelectric insulator layer can be used to implement a ferroelectric memory (i.e., storage) device. For example, an array of MIM devices with ferroelectric insulator layers and suitable transistor-based driving circuitry can thus serve as a compact ferroelectric memory array. A suitable high-k dielectric material that can be manufactured as a ferroelectric material is hafnium-zirconium-oxide (Hf₁₋ₓZrₓO₂), also denoted herein as HZO. The x in Hf₁₋ₓZrₓO₂ denotes the zirconium fraction, and 0<x<1. The binary oxide ZrO₂ corresponds to x=1, and the binary oxide HfO₂ corresponds to x=0. The orthorhombic phase of HZO is non-centrosymmetric with oxygen atoms are arranged to be able to respond to form polarizations in response to external electric fields, thereby being capable of being switched by application of electric field between positive and negative polarization states. The ferroelectric behavior of the orthorhombic crystal phase of HZO is a consequence of its non-centrosymmetric crystal structure.

Performance of an MIM structure is commonly characterized by metrics such as the breakdown voltage (VBD), time-dependent dielectric breakdown (TDDB), and leakage (LK). The MIM structure performance by such metrics can degrade in response to thermal annealing of the MIM structure. Such annealing may however occur, for example due to high temperature processing performed after formation of the MIM structure, or annealing to induce orthorhombic crystallization in the case of an MIM structure intended to perform as a ferroelectric device.

In MIM structures and corresponding fabrication methods disclosed herein, such degradation is mitigated by use of capping layers with predominantly tetragonal crystal phase. As disclosed herein, such capping layers improve metrics of the MIM structure (e.g., TDDB, VBD, LK), and thus improve device yield. The capping layers with predominantly tetragonal crystal phase mitigate degradation of during annealing. In the case of ferroelectric MIM structures, the MIM structure is more robust against the orthorhombic crystallization anneal.

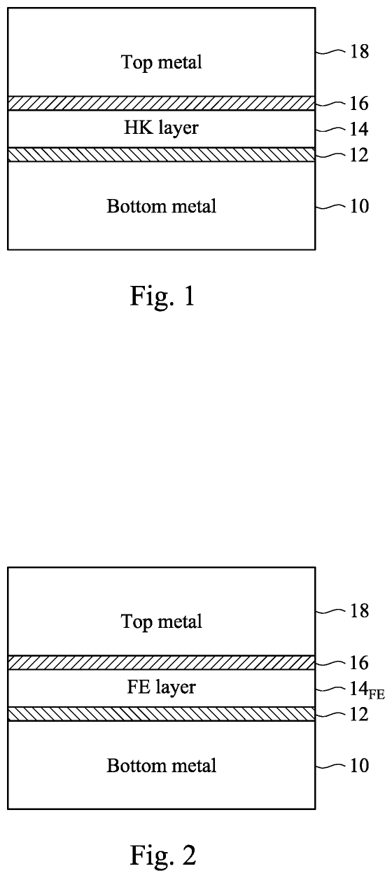

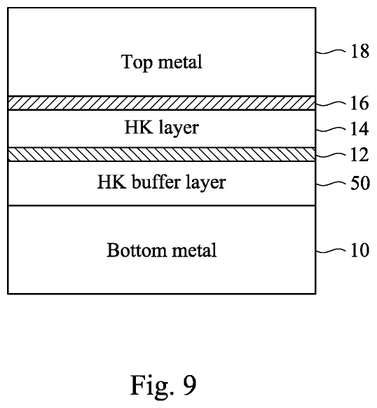

With reference to FIG. 1, a side sectional view is shown of an MIM device according to a first embodiment. The MIM structure includes a first metal 10, a first cap layer 12 disposed on the first metal 10, a high-k insulator layer (HK layer) 14 disposed on the first cap layer 12, a second cap layer 16 disposed on the HK layer 14, and a second metal 18 disposed on the second cap layer 16. In one suitable fabrication process (see FIG. 8), the order of formation is: formation of the first metal 10; followed by formation of the first cap layer 12; followed by formation of the HK layer 14; followed by formation of the second cap layer 16; followed by formation of the second metal 18. Hence, the first metal 10 is also referred to herein as first metal 10; the first cap layer 12 is also referred to herein as bottom cap layer 12; the second cap layer 16 is also referred to herein as top cap layer 16; and the second metal 18 is also referred to herein as top metal 18. The use of “top” and “bottom” do not denote any particular spatial orientation.

The bottom metal 10 suitably comprise an electrically conductive material such as: titanium nitride (TiN); tantalum nitride (TaN); an elemental metal such as titanium (Ti), aluminum (Al), tungsten (W), platinum (Pt), molybdenum (Mo), or alloys thereof; or so forth. As shown by these nonlimiting illustrative examples, the term “metal” as used herein is not limited to elemental metals or alloys thereof: rather, the term “metal” as used herein also encompasses other materials commonly used as electrical conductors in the semiconductor industry, such as TiN or TaN. The top metal 18 also suitably comprises an electrically conductive material such as TiN, TaN, an elemental metal such as Ti, Al, W, Pt, Mo, alloys thereof, or so forth. The top metal 18 may be the same type of metal as the bottom metal 10 (e.g., both TiN); or alternatively the top metal 18 and the bottom metal 10 may be different types metals (e.g., the bottom metal 10 could be W while the top metal 18 could be TaN).

The top and bottom cap layers 12 and 16 each comprise a dielectric material that has a tetragonal crystal phase. For example, in some embodiments, the percentage of the top and bottom cap layers 12 and 16 that is in the tetragonal phase is at least 80%; or said another way, the tetragonal phase percentage of the top and bottom cap layers 12 and 16 is at least 80%. In various embodiments, this can be achieved by suitable selection of the composition of the top and bottom cap layers 12 and 16, or by suitable doping of the top and bottom cap layers 12 and 16. The tetragonal phase has a unit cell with sides a, b, and c that are mutually orthogonal (i.e., mutually perpendicular), and with two sides (e.g., sides a and b) of equal length. If all three sides are of the same length (that is, a=b=c), then the tetragonal phase is more specifically a cubic phase. A cubic phase is also a tetragonal phase, that is, a cubic phase is an example of a tetragonal phase.

The insulator layer 14 comprises a high-k dielectric material, and hence is also referred to herein as an HK layer 14. The insulator layer 14 has a dielectric constant κ (=ϵᵣ) that is larger than the dielectric constant of silicon dioxide (SiO₂, κ=3.9). In some nonlimiting illustrative embodiments, the insulator layer 14 is a high-k dielectric material with a dielectric constant κ in a range of 30≤κ≤40. In some nonlimiting illustrative examples, the insulator layer 14 has an orthorhombic phase percentage of at least 70%. In some nonlimiting illustrative embodiments, the insulator layer is a ferroelectric material (which in some cases is obtained by having an orthorhombic phase percentage of at least 70%). In some nonlimiting illustrative embodiments, the bottom cap layer 12 has a thickness dbot that is less than or equal to 0.1 times a thickness dHK of the insulator layer 14

$$( that is , \frac{{d}_{bot}}{{d}_{HK}} \leq \frac{1}{10} ) ;$$

and the top cap layer 16 has a thickness dₜₒₚ that is less than or equal to 0.1 times the thickness d_{HK} of the insulator layer 14

$$( that is , \frac{{d}_{top}}{{d}_{HK}} \leq \frac{1}{10} ) .$$

An advantage of having

$$\frac{{d}_{bot}}{{d}_{HK}} \leq \frac{1}{10} and \frac{{d}_{top}}{{d}_{HK}} \leq \frac{1}{10}$$

is that these relatively thin cap layers reduces the overall thickness of dielectric material disposed between the bottom metal 10 and the top metal 18, thus keeping the total thickness d of the capacitance

$$C = \frac{{κε}_{0} A}{d}$$

low and hence keeping the capacitance C high.

In some embodiments, the cap layers 12 and 16 are made of the same high-k dielectric material as the HK layer 14, albeit possibly with a different fractional composition, and/or with doping of the cap layers 12 and 16 to enhance the tetragonal phase percentage as described in some illustrative embodiments herein. For example, in one nonlimiting illustrative example the cap layers 12 and 16 and the HK layer 14 may all be made of hafnium zirconium oxide, with the same or different zirconium fractions.

Without being limited to any particular theory of operation, the bottom cap layer 12 is believed to improve the properties of the insulator layer 14 (e.g., TDDB, VBD, LK) by at least one or more of the following mechanisms. If the insulator layer 14 is a binary or ternary or quaternary oxide and the bottom cap layer 12 is also a (possibly different) binary or ternary or quaternary oxide, then the bottom cap layer 12 is believed to reduce defects in the insulator layer 14 caused by oxygen deficiencies or holes. The bottom cap layer 12 may also provide an improved crystallographic template for the subsequent formation of the insulator layer 14, especially if the bottom layer 12 and the insulator layer 14 are made of materials with similar crystallographic structure (e.g., the bottom cap layer 12 being ZrO₂ or Hf₁₋ₓZrₓO₂ and the insulator layer 14 being Hf₁₋ₓZrₓO₂ , as a nonlimiting illustrative example). In some embodiments, the bottom cap layer 12 has a thickness of at least 0.4 nanometers to provide a stable and uniform film.

Without being limited to any particular theory of operation, the top cap layer 16 is believed to improve the properties of the insulator layer 14 (e.g., TDDB, VBD, LK) at least by protecting the insulator layer 14 during one or more thermal processes performed after formation of the MIM structure. For example, if the MIM structure is intended to be ferroelectric then these thermal processes could include an anneal to crystallize the insulator layer in a predominantly ferroelectric orthorhombic phase. In other examples, the one or more thermal processes could include elevated temperatures employed in depositing materials after formation of the MIM structure.

Because the bottom cap layer 12 and the top cap layer 16 perform different functions, it is contemplated for the bottom cap layer 12 and the top cap layer 16 to have different thicknesses, and/or for the bottom cap layer 12 and the top cap layer 16 to have different compositions. As just one nonlimiting illustrative example, in one embodiment the bottom cap layer 12 has a thickness of 0.4 nanometers and the top cap layer 16 has a thickness of 1.0 nanometers.

In operation, the MIM structure such as that of FIG. 1 or other MIM structure embodiments herein can serve as a capacitor for frequency filtering, noise reduction, DC isolation, or so forth. In some embodiments, the MIM structure may be formed during back end-of-line (BEOL) processing of an IC chip, although it is not limited to this setting. The bottom metal 10 and top metal 18 serve as electrodes or plates of the capacitive MIM structure, while the insulator layer 14 (and secondarily the dielectric cap layers 12 and 16) serve as the insulator structure of the MIM capacitor. In embodiments in which the insulator layer 14 is a ferroelectric material, the MIM structure can for example serve as a ferroelectric tunnel junction (FTJ), which can in turn, for example, serve as the storage element of a ferroelectric random access memory (FeRAM) that includes the FTJ and a transistor. The transistor can, for example, be a field-effect transistor (FET), and is suitably used to read and write bit values to the FTJ which serves as nonvolatile storage for the FeRAM.

With reference to FIG. 2, an embodiment of an MIM structure is described which includes the bottom metal 10, bottom cap layer 12, top cap layer 16, and top metal 18, as previously described with respect to the embodiment of FIG. 1; and further includes the insulator layer 14 as previously described with reference to FIG. 1 but which in the embodiment of FIG. 2 is specifically a ferroelectric insulator layer 14_{FE}. The ferroelectric insulator layer 14_{FE} comprises a ferroelectric phase, such as a non-centrosymmetric orthorhombic phase with oxygen atoms arranged to be able to respond to form polarizations in response to external electric fields, thereby being capable of being switched by application of electric field between positive and negative polarization states. The ferroelectric behavior of such an orthorhombic crystal phase is a consequence of its non-centrosymmetric crystal structure. In some nonlimiting illustrative embodiments, the ferroelectric insulator layer 14_{FE} may comprise an oxide selected from a group consisting of Hf₁₋ₓZrₓO₂ , SrBi₂Ta₂O₉, PbZrₓTi₁₋ₓ)₃, or BaTiO₃. In some embodiments, the insulator layer 14_{FE} comprises a ternary or quaternary oxide having a ferroelectric orthorhombic phase whose phase percentage in the insulator layer 14_{FE} is at least 70%, the bottom cap layer 12 comprises the ternary or quaternary oxide doped with a dopant, and top cap layer 16 comprises the ternary or quaternary oxide doped with the dopant; in which the dopant causes a tetragonal phase percentage of the bottom cap layer 12 to be at least 80% and causes the tetragonal phase percentage of the top cap layer 16 to be at least 80%.

With reference to FIG. 3, an embodiment of an MIM structure is described in which the insulator layer is a hafnium-zirconium-oxide (Hf₁₋ₓZrₓO₂ ) layer 14_{HZO}, the bottom cap layer is a bottom (or first) cap layer 12_{Zr-rich} comprising HZO with a higher zirconium fraction (i.e. larger value of x) than the HZO layer 14_{HZO}, and the top cap layer is a top (or second) cap layer 16_{Zr-rich} comprising HZO with a higher zirconium fraction (i.e. larger value of x) than the HZO layer 14_{HZO}. Put another way, the bottom and top cap layers 12_{Zr-rich} and 16_{Zr-rich} are HZO material that is zirconium-rich compared with the HZO layer 14_{HZO}. As previously noted, in some embodiments the bottom and top cap layers 12_{Zr-rich} and 16_{Zr-rich} each have a thickness that is 1/10^{th} or less than the thickness of the HZO layer 14_{HZO}.

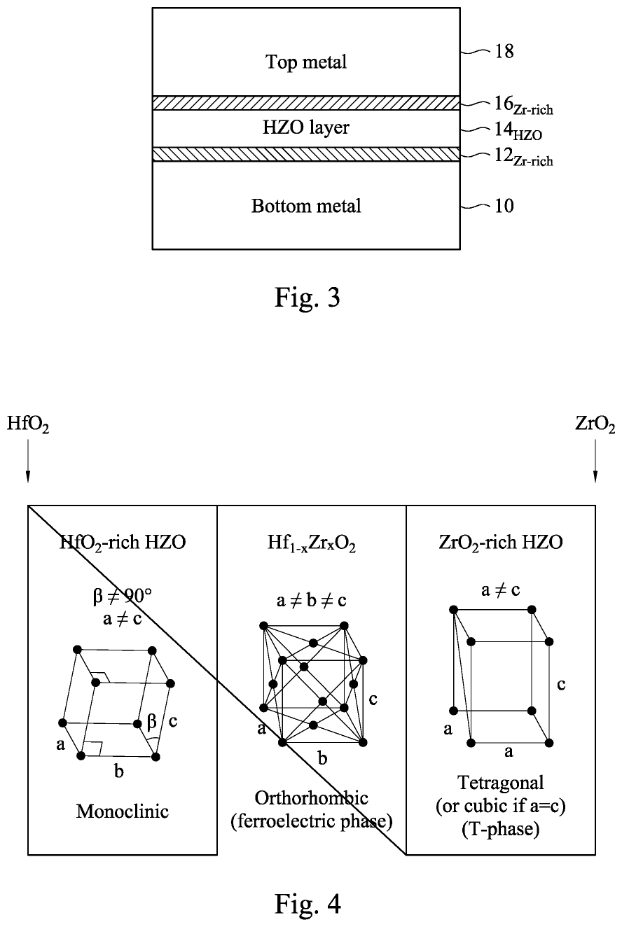

With continuing reference to FIG. 3 and with further reference to FIG. 4, it is explained why making the bottom and top cap layers 12_{Zr-rich} and 16_{Zr-rich} zirconium-rich compared with the HZO layer 14_{HZO} promotes the desired crystalline structures of the respective layers. FIG. 4 diagrammatically shows the stable crystal structure as a function of zirconium fraction, ranging from x=0 (the binary oxide HfO₂) to x=1 (the binary oxide ZrO₂). For the ternary compositions (HZO, where 0<x<1), these can be conceptually viewed as mixtures of HfO₂ and ZrO₂. As diagrammatically shown in FIG. 4, the stable crystal phase of ZrO₂ is a tetragonal crystal phase, while the stable crystal phase of HfO₂ is a monoclinic crystal phase. For intermediate values of the zirconium composition (i.e., intermediate mixtures of HfO₂ and ZrO₂), the stable phase of the ternary oxide HZO is an orthorhombic phase.

The stable orthorhombic phase of HZO is non-centrosymmetric with oxygen atoms are arranged to be able to respond to form polarizations in response to external electric fields, thereby being capable of being switched by application of electric field between positive and negative polarization states. The ferroelectric behavior of the orthorhombic crystal phase of HZO is a consequence of its non-centrosymmetric crystal structure. On the other hand, by making the HZO more zirconium-rich, as shown in FIG. 4, the stable crystal phase shifts to tetragonal. Hence, by employing a zirconium-rich HZO composition for the bottom and top cap layers 12_{Zr-rich} and 16_{Zr-rich}, the bottom and top cap layers 12_{Zr-rich} and 16_{Zr-rich} can be formed with a tetragonal phase percentage of at least 80%. The Zr fractions in the cap layers 12_{Zr-rich} and 16_{Zr-rich} and in the insulator layer 14_{HZO} to achieve the desired 80% or higher tetragonal phase percentage in the cap layers 12_{Zr-rich} and 16_{Zr-rich} and the desired 70% or higher orthorhombic phase (possibly after anneal) in the insulator layer 14_{HZO} is suitably determined by experimental test runs that are characterized by X-ray diffraction (XRD), electron backscatter diffraction (EBSD), or another characterization technique to assess the phase percentages of the layers. In some nonlimiting illustrative examples, a zirconium fraction x greater than about 20% is suitable to obtain the desired 80% or higher tetragonal phase percentage in the cap layers 12_{Zr-rich} and 16_{Zr-rich}.

In this regard, the as-deposited HZO layer may be amorphous, or may have an undesirable mixture of crystal phases. In particular, the as-deposited insulator layer 14_{HZO} may not have the desired 70% or higher orthorhombic crystal phase percentage. Hence, in some embodiments the formation of the layers of the MIM structure includes performing an anneal to crystallize the as-deposited insulator layer 14_{HZO} in a predominantly orthorhombic phase (e.g., orthorhombic phase percentage 70% or higher). The annealing is performed at a suitably high temperature for a sufficient time interval (e.g., ˜550° C. for about 5 minutes may be sufficient in some cases, as a nonlimiting illustrative example). Depending on the fabrication workflow of the IC containing the MIM structure, IC fabrication steps performed after forming the MIM device with the HZO insulator layer 14_{HZO} may provide sufficient annealing to obtain the desired orthorhombic crystal phase of 70% or higher, so that a dedicated anneal step for orthorhombic crystallization of the HZO may not be needed. XRD, EBSD, or other characterization methods can be performed on test runs with different anneal schedules to empirically determine a suitable anneal schedule for the insulator layer 14_{HZO}.

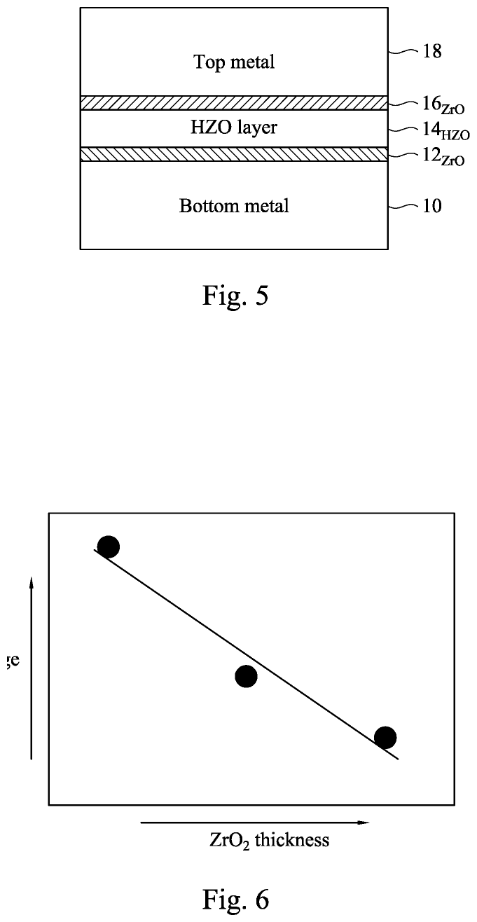

With reference to FIG. 5, an MIM structure according to a further embodiment is similar to the MIM structure of FIG. 3. However, the MIM structure of FIG. 5 replaces the zirconium-rich cap layers 12_{Zr-rich} and 16_{Zr-rich} of the embodiment of FIG. 3 with a respective bottom (i.e., first) ZrO₂ cap layer 12_{Zro} and top (i.e., second) ZrO₂ cap layer 16_{Zro}. With reference back to FIG. 4, this corresponds to the limiting case where the zirconium-rich cap layers are the binary oxide ZrO₂ (that is, zirconium fraction x=1).

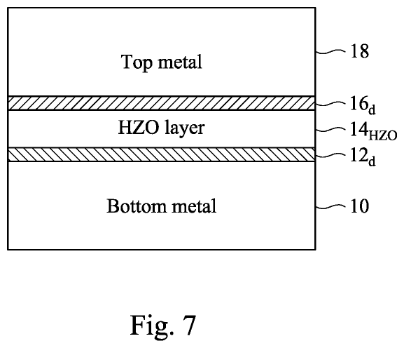

With reference to FIG. 6, experimental results are shown for an MIM structure substantially as shown in FIG. 5, that is, including an HZO layer 14_{HZO} capped by a bottom ZrO₂ cap layer 12_{Zro} and a top ZrO₂ cap layer 16_{Zro}. FIG. 6 plots the measured leakage (LK) of the MIM structure as a function of ZrO₂ thickness. As seen, the leakage decreases with increasing thickness of the ZrO₂ capping layers, thus demonstrating the effectiveness of the capping layers in improving leakage.

In the embodiments described with reference to FIGS. 3-6, the stable tetragonal phase of the cap layers is obtained by making the cap layers zirconium-rich (or pure ZrO₂ in the case of FIG. 5). Advantageously, this can be achieved in some embodiments in a single deposition chamber in a continuous deposition process, by varying the ratio of the zirconium and hafnium precursors appropriately during the deposition (i.e., higher zirconium precursor/hafnium precursor ratio during the deposition of the zirconium-rich cap layers 12_{Zr-rich} and 16_{Zr-rich}, and lower zirconium precursor/hafnium precursor ratio during the deposition of the insulator layer 14_{HZO}. For the embodiment of FIG. 5, the hafnium precursor may be shut off completely during deposition of the ZrO₂ cap layers 12_{ZrO} and 16_{ZrO}. The deposition chamber may, for example, be a chemical vapor deposition (CVD) chamber, a physical vapor deposition (PVD) chamber, or so forth. While using a single chamber to deposit both the cap layers and the HZO insulator layer 14_{HZO} can be efficient from a manufacturing viewpoint, it is alternatively contemplated to employ different chambers for depositing the cap layers and the bulk HZO insulator layer 14_{HZO} , respectively.

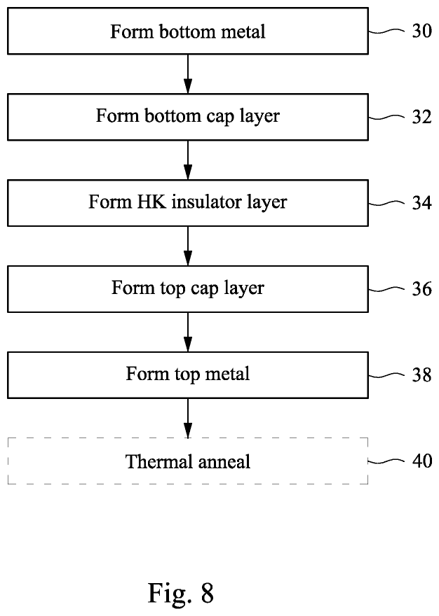

With reference now to FIG. 7, in some embodiments doping with a dopant is employed to obtain the bottom and top cap layers with the desired high (e.g. greater than or equal to 70%) tetragonal phase percentage. The MIM structure of FIG. 7 is similar to that of FIG. 3, and includes the bottom metal 10 and top metal 18 sandwiching an HZO insulator layer 14_{HZO} . However, in the embodiment of FIG. 7, the bottom cap layer comprises a doped HZO cap layer 12_{d} that is doped with a dopant that causes the tetragonal phase percentage of the bottom doped HZO cap layer 12_{d} to be at least 80%. Similarly, the top cap layer comprises a doped HZO cap layer 16_{d} that is doped with a dopant that causes the tetragonal phase percentage of the top doped HZO cap layer 16_{d} to be at least 80%. The dopant used may, for example, be silicon (Si), germanium (Ge), aluminum (Al), yttrium (Y), scandium (Sc), gadolinium (Gd), or a combination thereof. Table 1 provides the stable phase of HZO predicted to be achieved by the minimum doping concentration (in percent) for these various dopants. As previously noted, the stable cubic phase obtainable using Y, Sc, or Gd is a specific example of a tetragonal phase. The minimum doping concentration values listed in Table 1 are theoretical estimates, and in practice lower concentrations (e.g., closer to about 5%-10%) may be sufficient to obtain the desired tetragonal phase for the bottom and top doped HZO cap layers 12d and 16d. XRD, EBSD, or other characterization methods can be performed on test runs with different doping levels for the bottom and top doped HZO cap layers 12d and 16d to empirically determine suitable doping levels for obtaining the desired tetragonal phase for these layers. Moreover, it is to be appreciated that Table 1 provides some illustrative suitable dopants, and other dopant species may be suitable for doping the doped HZO cap layers 12_{d} and 16_{d} to obtain the desired tetragonal phase. Furthermore, while described with reference to the example of FIG. 7 in which the ferroelectric insulator layer 14_{HZO} is HZO and the bottom and top doped cap layers 12_{d} and 16_{d} are also HZO, more generally such doping can be used to obtain tetragonal bottom and top capping layers for MIM structures with other types of ferroelectric material, such as Hf₁₋ₓZrₓO₂, SrBi₂Ta₂O₉, PbZrₓTi₁₋ₓO₃, or BaTiO₃.

TABLE 1

| | | Minimum doping |
|---|---|---|
| Dopant | Stable phase | concentration |
| Silicon (Si) | Tetragonal | 11% |
| Germanium (Ge) | Tetragonal | 19% |
| Aluminum (Al) | Tetragonal | 11% |
| Yttrium Y | Cubic | 11% |
| Scandium (Sc) | Cubic | 13% |
| Gadolinium (Gd) | Cubic | 10% |

With reference now to FIG. 8, a method of manufacturing an MIM structure such as the illustrative examples of FIG. 1-3, 5, or 7 is presented by way of a flowchart. In an operation 30, the bottom (or first) metal 10 is formed. In some embodiments, the bottom metal 10 may be deposited, for example, as an electrically conductive material such as TIN, TaN, an elemental metal (e.g., Ti, Al, W, Pt, Mo, et cetera), or alloys thereof. The bottom metal 10 may be formed, for example, by physical vapor deposition (PVD), atomic layer deposition (ALD), electrolysis, or another suitable technique. In some embodiments in which the MIM structure is fabricated during back end-of-line (BEOL) processing, the bottom metal 10 may comprise a patterned metallization layer of a metallization stack formed during the BEOL processing. In this case, the operation 30 may entail forming the patterned metallization by depositing a blanket metal layer on an underlying intermetal dielectric (IMD) material and applying photolithographically patterned etching to form the patterned metallization layer which includes the bottom metal 10.

In an operation 32, the bottom (or first) cap layer is formed, for example by PVD, ALD, chemical vapor deposition (CVD), or another suitable deposition technique. The detailed formation depends on the type of cap layer. For example, to implement formation of an MIM structure in accordance with the embodiment of FIG. 3, the bottom cap layer 32 is suitably formed by depositing HZO with a suitably high zirconium fraction as previously discussed with reference to FIG. 3. To implement formation of an MIM structure in accordance with the embodiment of FIG. 5, the bottom cap layer 32 is suitably formed by depositing ZrO₂. To implement formation of an MIM structure in accordance with the embodiment of FIG. 7, the bottom cap layer 32 is suitably formed as HZO doped with the tetragonal phase-inducing dopant.

In an operation 34, the high-k insulator layer is formed. For example, to implement formation of an MIM structure in accordance with one of the embodiments of FIG. 3, 5, or 7, the insulator layer is suitably formed as an HZO layer 14_{HZO}, for example by PVD, ALD, CVD, or another suitable deposition technique.

In an operation 36, the top (or second) cap layer is formed, for example by PVD, ALD, CVD, or another suitable deposition technique. As with the operation 32, the detailed formation depends on the type of cap layer.

The operations 32, 34, and 36 may in some embodiments be performed by a single deposition technique (e.g., PVD, ALD, CVD, et cetera) using the same deposition tool (e.g., same PVD chamber, same ALD chamber, same CVD chamber, et cetera). In such embodiments, the implementation of the successive operations 32, 34, and 36 entails adjusting or switching on or off precursor flows appropriately. For example, to implement an MIM structure in accordance with the embodiment of FIG. 3, the zirconium precursor flow and/or hafnium precursor flow can be adjusted to control the zirconium fraction of each layer 12_{Zr-rich}, 16_{HZO}, and 18_{Zr-rich}. To implement an MIM structure in accordance with the embodiment of FIG. 5, the zirconium precursor flow can be turned off during deposition of the cap layers 12_{ZrO} and 18_{ZrO}. To implement an MIM structure in accordance with the embodiment of FIG. 7, the dopant precursor flow can be turned on during deposition of the bottom doped cap layer 12_{d}, then turned off for deposition of the HZO insulator layer 14_{HZO}, and the dopant precursor flow then turned back on for deposition of the top doped cap layer 18_{d}. Using a single deposition tool to perform the three operations 32, 34, and 36 has certain advantages such as workflow efficiency and minimizing the potential for surface contamination during wafer transport between deposition tools. However, it is also contemplated to perform the operations 32, 34, and 36 using two or even three different deposition tools.

In an operation 38, the top (or second) metal 18 is formed. In some embodiments, the top metal 18 may be deposited, for example, as an electrically conductive material such as TiN, TaN, an elemental metal (e.g., Ti, Al, W, Pt, Mo, et cetera), or alloys thereof. The top metal 18 may be formed, for example, by PVD, ALD, electrolysis, or another suitable technique. In embodiments in which the MIM structure is fabricated during BEOL processing, the top metal 18 may comprise a second patterned metallization layer of the metallization stack formed during the BEOL processing. The bottom (or first) metal 10 formed in the operation 30 and the top (or second) metal 18 formed in the operation 38 may be formed of the same material, or may be formed of different materials.

With continuing reference to FIG. 8, the MIM structure fabrication process may optionally include a thermal anneal 40. For example, as previously discussed the formation of certain ferroelectric materials may include the thermal anneal 40 to crystallize the material (e.g., HZO) in the ferroelectric orthorhombic phase. If the thermal anneal 40 is performed, it may be a dedicated thermal anneal performed specifically to crystallize the insulator layer in the ferroelectric orthorhombic phase (e.g., so that post-anneal the orthorhombic phase percentage of the HZO insulator layer is at least 70% causing the HZO insulator layer to be ferroelectric). Alternatively, the thermal anneal 40 could be implemented by way of further processing performed after the operation 38 in the course of the overall IC fabrication workflow, which includes sufficient heating to perform the desired crystallization in the orthorhombic phase. For example, the thermal anneal 40 could comprise elevated temperature intervals used for depositing a subsequent layer (e.g. silicon nitride, an oxide insulator, or so forth), as one nonlimiting illustrative example. In general, the thermal anneal 40 may entail rapid thermal annealing (RTA), forming gas annealing, high pressure anneal (HPA), various combinations thereof, or so forth.

The illustrative MIM structures of FIGS. 1-3, 5, and 7 include the bottom metal 10, the bottom cap layer 12, 12_{Zr-rich}, 12_{ZrO}, or 12_{d}, the insulator layer 14, 14_{FE}, or 14_{HZO}, the top cap layer 16, 16_{Zr-rich}, 16_{ZrO}, or 16_{d}, and the top metal layer 18. However, the MIM structure may optionally include additional layers.

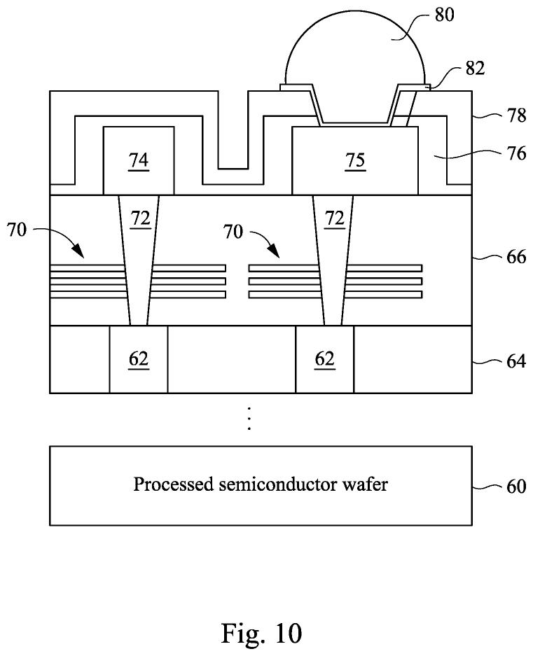

With reference to FIG. 9, for example, an MIM structure is shown which is similar to the MIM structure of FIG. 1, including the bottom metal 10, the bottom cap layer 12, the insulator layer 14, the top cap layer 16, and the top metal layer 18. However, the MIM structure of FIG. 9 further includes a high-k buffer layer 50 interposed between the bottom metal 10 and the bottom cap layer 12. The high-k buffer layer 50 may, for example, provide increased overall thickness of the total dielectric interposed between the metal layers 10 and 18 to increase the breakdown voltage (VBD) of the MIM structure. As a more specific example, if the insulator layer 14 is a ferroelectric layer and the high-k buffer layer 50 is a non-ferroelectric layer, this combination can provide a larger insulator thickness to increase VBD while keeping the ferroelectric layer 14 thinner to maintain high switching speed for the FTJ or other ferroelectric device.

As previously noted, in some embodiments the MIM structure may be formed during BEOL processing, for example serving as a BEOL capacitor or a FTJ formed in the BEOL processing.

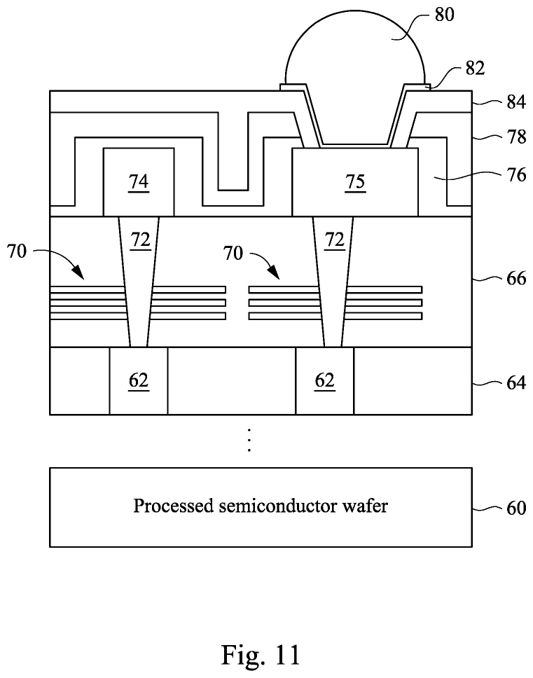

With reference to FIGS. 10 and 11, two illustrative embodiments by way of sectional view are shown of examples of incorporation of MIM structures into IC devices. A processed semiconductor wafer 60 is diagrammatically indicated. In front end-of-line (FEOL) processing, a silicon wafer is processed by steps such as dopant diffusion, epitaxy, etching, deposition, and/or so forth controlled by photolithographic patterning to form electronic devices (e.g., transistors, resistors, and so forth) in a silicon wafer, silicon-on-insulator (SOI) wafer, or other semiconductor substrate to form the processed semiconductor wafer 60. Thereafter, the BEOL processing forms a metallization stack on the IC chip or wafer 60. The BEOL processing typically entails an iterative process of depositing a blanket metal layer, performing photolithographic patterning on the blanket metal layer to form a patterned metallization layer, depositing intermetal dielectric material (IMD), and repeating to form each successive patterned metallization layer of the metallization stack. FIGS. 10 and 11 diagrammatically depict only a topmost metallization layer 62 of the metallization stack, with surrounding dielectric material 64. This surface is suitably planarized, for example by chemical-mechanical polishing (CMP).

An under-bump metallization (UBM) is then formed to enable bonding the IC to another chip or to a printed circuit board (PCB) or other electrical or electronic component via a ball grid array (BGA). The UBM includes a dielectric layer 66, with MIM structures 70 embedded in the dielectric material 66. Vias 72 accessing the topmost patterned metallization layer 62 through the dielectric layer 66 are formed by etching via openings through the dielectric material 66 using photolithographically controlled etching and filling the via openings with electrically conductive material such as tungsten as a nonlimiting illustrative example. The MIM structures 70 are included to provide noise fluctuation suppression for signals passing through the UBM. The UBM further includes a redistribution layer (RDL) 74 and bonding pads 75 (one illustrated bonding pad 75 is shown in each of FIGS. 10 and 11) formed on the dielectric material 66 and coated with a further dielectric layer 76 and passivation layer 78.

In the illustrative example of FIG. 10, an illustrative bonding bump (i.e., ball) 80 is shown bonded to the illustrative bonding pad 75 through a photolithographically defined etched opening in the dielectric and passivation layers 76, 78. An optional interfacing material 82, such as a pre-solder, flux material, organic solderability preservative, or the like may be applied to the bonding pad 75 prior to attaching the bonding bump 80. In a typical sequence, the bonding bump 80 comprises solder and is heated to form the bond.

The UBM of the example of FIG. 11 is similar to that of FIG. 10, except that an additional polyimide layer 84 is formed on the passivation layer 78. The polyimide layer 84 may, for example, serve as a solder mask or so forth.

It is to be appreciated that the illustrative noise fluctuation suppression application of the MIM structures of the examples of FIGS. 10 and 11 is merely a nonlimiting illustrative example. More generally, the disclosed MIM structures can be employed in any application that utilizes an MIM structure, and the embodiments that employ a ferroelectric insulator layer may be employed in an FTJ, FE-RAM, or any other application of a ferroelectric MIM structure.

In the following, some further embodiments are described.

In a nonlimiting illustrative embodiment, a method of manufacturing a metal-insulator-metal (MIM) device is disclosed. The method includes: forming a first cap layer on a first metal, the first cap layer comprising a composition including at least zirconium and oxygen and having a tetragonal crystal phase; forming a Hf₁₋ₓZrₓO₂ insulator layer on the first cap layer; forming a second cap layer on the Hf₁₋ₓZrₓO₂ insulator layer, the second cap layer comprising a composition including at least zirconium and oxygen and having the tetragonal crystal phase; and forming a second metal on the second cap layer.

In a nonlimiting illustrative embodiment, a method of manufacturing a metal-insulator-metal (MIM) device is disclosed. The method includes: forming a first cap layer on a first metal, wherein the first cap layer comprises a dielectric material with a tetragonal phase percentage that is at least 80%; forming an insulator layer on the first cap layer; forming a second cap layer on the insulator layer, wherein the second cap layer comprises a dielectric material with a tetragonal phase percentage that is at least 80%; and forming a second metal on the second cap layer.

In a nonlimiting illustrative embodiment, a metal-insulator-metal (MIM) device includes: a first metal; a first cap layer disposed on the first metal, the first cap layer comprising a dielectric material having a tetragonal crystal phase; an insulator layer disposed on the first cap layer; a second cap layer disposed on the insulator layer, the second cap layer comprising a dielectric material having the tetragonal crystal phase; and a second metal disposed on the second cap layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a metal-insulator-metal (MIM) device, the method comprising:
forming a first cap layer on a first metal, the first cap layer comprising a composition including at least zirconium and oxygen and having a tetragonal crystal phase;
forming a Hf₁₋ₓZrₓO₂ insulator layer on the first cap layer;
forming a second cap layer on the Hf₁₋ₓZrₓO₂ insulator layer, the second cap layer comprising a composition including at least zirconium and oxygen and having the tetragonal crystal phase; and
forming a second metal on the second cap layer.

2. The method of claim 1, wherein the tetragonal phase percentage of the first cap layer is at least 80%, and the tetragonal phase percentage of the second cap layer is at least 80%.

3. The method of claim 1, wherein the orthorhombic phase percentage of the Hf₁₋ₓZrₓO₂ insulator layer is at least 70% causing the Hf₁₋ₓZrₓO₂ insulator layer to be ferroelectric.

4. The method of claim 1, wherein the first cap layer comprises a Hf₁₋ₓZrₓO₂ composition that is more zirconium-rich than the Hf₁₋ₓZrₓO₂ insulator layer, and the second cap layer comprises a Hf₁₋ₓZrₓO₂ composition that is more zirconium-rich than the Hf₁₋ₓZrₓO₂ insulator layer.

5. The method of claim 1, wherein the first cap layer comprises ZrO₂ and the second cap layer comprises ZrO₂.

6. The method of claim 1, wherein the first cap layer comprises a Hf₁₋ₓZrₓO₂ composition that is doped with a dopant, and second cap layer comprises a Hf₁₋ₓZrₓO₂ composition that is doped with the dopant, wherein the dopant causes the tetragonal phase percentage of the first cap layer to be at least 80% and the dopant causes the tetragonal phase percentage of the second cap layer to be at least 80%.

7. The method of claim 6, wherein the dopant comprises silicon (Si), germanium (Ge), aluminum (Al), yttrium (Y), scandium (Sc), gadolinium (Gd), or a combination thereof.

8. The method of claim 6, wherein the Hf₁₋ₓZrₓO₂ insulator layer, the Hf₁₋ₓZrₓO₂ composition of the first layer, and the Hf₁₋ₓZrₓO₂ composition of the second layer all have the same zirconium fraction x.

9. The method of claim 1, wherein a ratio of a thickness of the first cap layer to the Hf₁₋ₓZrₓO₂ insulator layer is 0.1 or less, and a ratio of a thickness of the second cap layer to the Hf₁₋ₓZrₓO₂ insulator layer is 0.1 or less.

10. The method of claim 9, wherein the thickness of the first cap layer is less than the thickness of the second cap layer.

11. The method of claim 1, further comprising:
prior forming the first cap layer on the first metal, forming a buffer dielectric layer on the first metal whereby the first metal is formed on the buffer dielectric layer.

12. A method of manufacturing a metal-insulator-metal (MIM) device, the method comprising:
forming a first cap layer on a first metal, wherein the first cap layer comprises a dielectric material with a tetragonal phase percentage that is at least 80%;
forming an insulator layer on the first cap layer;
forming a second cap layer on the insulator layer, wherein the second cap layer comprises a dielectric material with a tetragonal phase percentage that is at least 80%; and
forming a second metal on the second cap layer.

13. The method of claim 12, wherein the insulator layer comprises a ferroelectric phase.

14. The method of claim 13, wherein the insulator layer comprises an oxide selected from a group consisting of Hf₁₋ₓZrₓO₂ , SrBi₂Ta₂O₉, PbZrₓTi₁₋ₓO₃, or BaTiO₃. 15 The method of claim 13, wherein the insulator layer comprises a ternary or quaternary oxide having a ferroelectric orthorhombic phase whose phase percentage in the insulator layer is at least 70%, the first cap layer comprises the ternary or quaternary oxide doped with a dopant, and second cap layer comprises the ternary or quaternary oxide doped with the dopant, wherein the dopant causes a tetragonal phase percentage of the first cap layer to be at least 80% and causes the tetragonal phase percentage of the second cap layer to be at least 80%.

16. The method of claim 12, wherein the insulator layer comprises a ferroelectric Hf₁₋ₓZrₓO₂ composition, and the first cap layer comprises ZrO₂ or a Hf₁₋ₓZrₓO₂ composition that is more zirconium-rich than the insulator layer, and the second cap layer comprises ZrO₂ or a Hf₁₋ₓZrₓO₂ composition that is more zirconium-rich than the insulator layer. 17 The method of claim 12, wherein a ratio of a thickness of the first cap layer to the insulator layer is 0.1 or less, and a ratio of a thickness of the second cap layer to the insulator layer is 0.1 or less.

18. The method of claim 12, further comprising:
prior forming the first cap layer on the first metal, forming a buffer dielectric layer on the first metal whereby the first metal is formed on the buffer dielectric layer.

19. A metal-insulator-metal (MIM) device comprising:
a first metal;
a first cap layer disposed on the first metal, the first cap layer comprising a dielectric material having a tetragonal crystal phase;
an insulator layer disposed on the first cap layer;
a second cap layer disposed on the insulator layer, the second cap layer comprising a dielectric material having the tetragonal crystal phase; and
a second metal disposed on the second cap layer.

20. The metal-insulator-metal (MIM) device of claim 19, wherein:
the insulator layer comprises a ferroelectric Hf₁₋ₓZrₓO₂ material; and
the first cap layer comprises ZrO₂ or a Hf₁₋ₓZrₓO₂ composition that is more zirconium-rich than the insulator layer, and the second cap layer comprises ZrO₂ or a Hf₁₋ₓZrₓO₂ composition that is more zirconium-rich than the insulator layer.
